(19) United States
(12) Patent Application Publication
(10) Pub. No.: US 2011/0017276 A1
(43) Pub. Date: Jan. 27, 2011

(54) SUN TRACKER DEVICE

(76) Inventors: Vincenzo Boffa, Milano (IT); Michele Galbusera, Milano (IT); Giuseppe Grassano, Milano (IT); Fabio Roncella, Milano (IT); Franco Peruzzotti, Milano (IT)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/935,522

(22) PCT Filed: Mar. 31, 2008
(86) PCT No.: PCT/IT08/00213

§ 371 Date: Sep. 29, 2010

(51) Int. Cl. H01L 31/052; F24J 2/38

(52) U.S. Cl. 136/246; 126/606

(57) ABSTRACT

A sun tracker device includes a base frame provided with a track that is at least in part circular; a support structure, of at least one photoreceiver module, the support structure being slidably associated with the track and including a reference plane for the coupling to the at least one photoreceiver module; a first motor group for controlling the movement of the support structure on the track around a substantially vertical axis; and at least one movement member of the at least one photoreceiver module around a respective substantially horizontal axis. The reference plane is tilted, with respect to a support plane of the device, by an angle of predetermined amplitude. An optimal compromise is achieved between maximisation of the energy yield and minimisation of the device size, at the same time ensuring an easy access to the components of the device for the maintenance operations.

The present invention relates to a sun tracker device.

Throughout the present description and in the subsequent claims, the expression: “sun tracker device”, is used to indicate a device adapted to appropriately orient suitable photoreceiver modules with respect to the sun and to follow the movement of the sun above the horizon from east to west during the day by maintaining the desired orientation of the modules.

Throughout the present description and in the subsequent claims, the expression: “photoreceiver module”, is used to indicate any element or device provided with a collection surface of the incident solar radiation.

Sun tracker devices are typically used for converting solar energy into other forms of energy, such as electrical or thermal energy.

Among the known sun tracker devices, the so-called “two-axis” trackers are particularly efficient from the energy conversion standpoint; in these, the solar radiation collection modules are mounted on a frame that can be moved around a vertical axis, each module being in turn movable, separately or simultaneously, around a respective horizontal axis. Such devices allows the orientation of the photoreceiver modules to be modified while the position of the sun changes during its passage from sunrise to sunset, always maintaining a desired orientation, which is that in which the detection surface of such modules is in a position substantially perpendicular to the incident solar light beam. The effective area of the solar radiation collection surface is thus maximised, along with, consequently, the energy output of the device.

Throughout the following present description and in subsequent claims, the expression: “effective area of the solar radiation collection surface”, is used to indicate the area of that part of the aforementioned surface which is actually hit by the solar rays and which therefore actually operates in the collection of the solar radiation.

In addition, throughout the following present invention and subsequent claims, the movement of the photoreceiver modules around the vertical axis is often indicated also with the expression: “azimuth movement”, while the movement of the photoreceiver modules around the horizontal axis will often be indicated also with the expression “altitude movement”.

In the specific case of the conversion of solar energy into electrical energy, the photoreceiver modules typically comprise photovoltaic cells assembled in flat panels. Such cells are adapted to collect the incident solar radiation regardless of the inclination of the solar rays with respect to the direction perpendicular to the detection surface of the cells.

The photovoltaic cells can also be assembled in modules of the concentration-type; such modules in particular comprise an optical group adapted to collect and concentrate, on the cells' photosensitive element, only the light rays coming from the direction normal to the optical group. For the correct functioning of the concentration modules, it is necessary that the direction of the solar rays coming from the solar disc be perfectly orthogonal to the cells' detection surface, with a tolerance of several tenths of degree. Concentration modules of the aforesaid type are described, for example in “Development and performance analysis of the phocus C-module”, presented at the International Conference of Solar Concentrators for the Generation of Electricity and Hydrogen, 12-16 Mar. 2007, El Escorian (Spain), and taken from Internet on 28 Mar. 2008, on the site http://www.ene1.portici.enea.it/Pubblicazioni/2007/Madrid_E NEA_Phocus%20Module.pdf.

US 2004/0216734 discloses a sun tracker device comprising a plurality of concave parabolic reflectors mounted on a frame according to a parallel row configuration. The frame is horizontal and is movable on a circular track integral with a support base, so to be able to rotate on the support base around a vertical axis. The reflectors are kinematically connected to each other by means of a mechanical deviation system that permits the movement of the reflectors of each row around a horizontal axis and the synchronous movement of the reflectors of one row with the reflectors of the other rows. The frame rests on four carriages, each provided with three wheels, one of which arranged with the axis orthogonal to that of the other two.

WO 2006/114457 discloses various embodiments of a sun tracker device comprising a plurality of concentration photovoltaic cells arranged in parallel rows. In a first embodiment, the photovoltaic cell rows are grouped in modules installed on a horizontal platform associated with a base plate rotatable around a vertical axis. In a second embodiment, the horizontal platform is in a raised position with respect to the ground. In a third embodiment, the photovoltaic cell rows are installed on a horizontal platform arranged on the top of a pole rotatable around a vertical axis. In a fourth embodiment, the photovoltaic cell rows are installed on a platform rotatable around an axis which is tilted with respect to the horizontal plane. In all the embodiments, each row of modules can be moved around a respective longitudinal axis.

U.S. Pat. No. 4,209,231 discloses a sun tracker device comprising a plurality of mirrors arranged close to each other so to form a rectangular array that can be moved as a single block around a horizontal axis. Such array is associated with a frame that can be moved on a circular track, with circular section, on which four carriages rest, each carriage being provided with two wheels arranged so that the respective axes are orthogonal to each other.

U.S. Pat. No. 4,129,360 discloses a heliostat comprising a reflecting panel associated with a triangular frame fixed to the ground at a vertex thereof and slidable on a track defined by a circular sector, by means of wheels provided at the other vertices thereof. The reflective panel is capable of rotating around a horizontal axis by means of a chain system (or closed ring cable system), in which the chain is associated with the top of the panel and housed in a bar hinged, at a free end thereof, to one of the vertices of the triangular frame.

U.S. Pat. No. 4,883,340 discloses a lighting system for building comprising a system of mirrors installed in fixed position perpendicular to a plane having a fixed inclination of 25° angle with respect to the horizontal plane. The frame that supports the mirrors can be rotated by means of a toothed ring which engages on a motorised toothed pulley.

The Applicant has devised a new type of sun tracker of the “two-axis” type that is suitable for supporting photoreceiver modules of different type (thus also of the concentration-type), and capable of ensuring high energy yields, irrespective of the type of photoreceiver module supported. In this respect, the Applicant has also contemplated the need to manufacture a sun tracker with limited visual impact and reduced plan dimensions, so to be able to install it even in urban and suburban areas with limited surface extension, at the same time ensuring an easy access to the various components of the tracker so to permit maintenance operations.

The Applicant has observed that the aforementioned needs are in part conflicting.

The Applicant has in fact observed that, in order to attain high energy yields, it is necessary to maximise the solar radiation collection area of the single modules and the density of modules on the installation surface, at the same time taking care to minimise the mutual shading between the various modules of a single tracker and/or between the modules of different trackers of a plant. This need implies a high plan extension of the tracker (in the case in which the modules are arranged on parallel rows on a structure with prevalently horizontal extension) and/or height extension (in the case in which the modules are arranged on a single tilted plane) and a difficult access/attainability of the various components of the tracker during the installation and/or maintenance operations, due to the height of the structure (in the case of tracker with prevalently vertical extension) and to the reduced space between the different trackers of the plant (in the case of tracker with prevalently horizontal extension).

The Applicant has also observed that, depending on the geographical latitude of the installation site of the solar tracker, identical tracker angles of identical photoreceiver modules correspond to different energy yields. This is due to the fact that with the change of latitude, the inclination of the solar rays varies with respect to the Earth, given the same orientation of the modules' detection surface with respect to the sun, and thus the effective area of the solar radiation collection surface varies. According to the Applicant, it is therefore advantageous, with the goal of maximising the energy yield of the tracker, to ensure that the detection surface of the modules is always appropriately oriented with respect to the incident solar rays. This need, however, must be compared with the aforementioned ones to guarantee limited visual impact, reduced plan dimensions and a lack of mutual shading.

The Applicant, with the goal of satisfying the partly conflicting needs set forth above, has found that by mounting the photoreceiver modules of a sun tracker device of the “two-axis” type on a plane tilted by an angle of predetermined amplitude with respect to a support plane of the device, it is possible to reduce the minimum angle of tilt which the single modules must have with respect to the ground so that there is no mutual shading. This allows maximising the energy yield of the device, since the Sun can be pointed to for a longer time during the day, at the same time limiting the size and visual impact of the device and ensuring an easy access to the components of the device in the maintenance operations.

The present invention therefore relates to a sun tracker device comprising:
a base frame provided with a track that is at least in part circular, said base frame defining a support surface;
a support structure of at least one photoreceiver module, the support structure being slidably associated with the track and comprising a reference plane for the coupling to said at least one photoreceiver module;
a first motor group for controlling the movement of the support structure on the track around a substantially vertical axis;
at least one movement member of said at least one photoreceiver module around a respective substantially horizontal axis;
   wherein said reference plane is tilted, with respect to said support plane, by an angle of predetermined amplitude.

Advantageously, the device of the present invention provides for an azimuth and altitude movement of the photoreceiver modules. It is therefore possible to modify the orientation of the photoreceiver modules with the change of the Sun's position during its passage above the horizon from sunrise to sunset, always maintaining the detecting surfaces of such modules in a position substantially perpendicular to the incident solar light beam.

Still more advantageously, the provision of the photoreceiver modules on a reference plane tilted by a predetermined angle with respect to the support plane of the device allows reducing the minimum tilt angle the single modules must have with respect to the support surface, in order to prevent the mutual shading of the modules. This allows, given the same plan dimensions of the device, a greater density of modules and a correct tracking of the sun for a longer time during the day with respect to the solutions of the prior art, in which the modules are arranged on a plane substantially parallel to the support plane.

With the device of the present invention, finally, an optimal compromise between maximisation of the energy yield of the device and minimisation of the device extension in the vertical direction is achieved, at the same time ensuring an easy access to the components of the device for the maintenance operations.

In particular, in the device of the present invention, the drawbacks of the traditional prevalently vertically extended trackers are minimised—i.e. these require a heavy foundation, and due to the vertical extension, they are sensitive to winds, makes difficult the maintenance operations and have particularly extended shading which obliges large distances between the trackers of a plant. Furthermore, the drawbacks of the traditional prevalently horizontally extended trackers are also minimised—i.e. here the limited space between the trackers of a plant makes difficult the maintenance operations and, in any case, the considerable plan dimensions of the tracker makes the structure complex from the structural and installation standpoint.

The device of the present invention therefore has, in addition to high efficiency from the energy production standpoint, reduced plan dimensions, limited visual impact and ease of access for maintenance operations. It is therefore suitable for also being installed in urban or suburban areas and/or areas with limited surface extension. The aforementioned advantageous characteristics, even if attainable in the case the device of the present invention is of great size, are particularly evident in those cases wherein the device has dimensions such to house photoreceiver modules for an overall peak power of a few KWattₚ. In these cases, in fact, the device can have very compact dimensions (typically on the order of a few meters), which are compatible for providing a directly onsite installation without the need to use heavy transport and installation machines (crane, in particular). This leads to considerable advantages in terms of production, transport and installation costs.

The present invention can have all or some of the preferred following characteristics.

In a preferred embodiment of the device of the present invention, the tilt angle of the aforementioned reference plane with respect to the support plane has an amplitude greater than 5°. In a further preferred embodiment of the device of the present invention, the aforementioned tilt angle has an amplitude lower than 50°.

In a first particularly preferred embodiment of the device of the present invention, the aforementioned tilt angle has an amplitude between about 5° and about 50°.

In a second particularly preferred embodiment of the device of the present invention, the aforementioned tilt angle has an amplitude between about 10° and about 30°.

In a third particularly preferred embodiment of the device of the present invention, the aforementioned tilt angle has an amplitude between about 15° and about 25°.

In the aforementioned particularly preferred embodiments, the device of the present invention therefore advantageously has an extremely reduced vertical extension, thus overcoming all the drawbacks mentioned above with reference to the trackers of the prior art with a prevalently vertical extension. In particular, the limited height extension of the device of the present invention, in addition to being advantageous in case of installations in zones with strong winds and/or on roofs of buildings, causes a limited visual impact that makes the device of the present invention particularly suitable for installation in urban or suburban zones. In addition thereof, the reduced height of the device of the present invention ensures that cement foundations are not necessary for the stable anchoring of the same on the installation surface.

As an example, considering a tilt of about 15° between the aforementioned reference plane and the support plane, the height of the device of the present invention is therefore approximately equal to about a quarter of the side of the support frame of the photoreceiver modules. For example, considering a square frame having a 4 m side, the height of the device is about 1 m. It is therefore evident how the height extension of the device of the present invention is in fact extremely reduced.

In a preferred embodiment thereof, the device according to the present invention comprises at least one adjustment member of the tilt of the aforementioned reference plane with respect to the support plane.

Advantageously, such feature confers high application and use flexibility to the device of the present invention, permitting the identification of an optimal installation configuration for obtaining high energy yield depending on the latitude of the specific geographic location of the installation site and on the shape of the support surface of the installation site itself.

For example, in the device of the present invention, it is advantageously possible to increase the tilt angle of the aforementioned reference plane in those cases where it is desired to reduce the incidence angle of the solar rays, above which there is no mutual shading, for a certain density of modules on the reference plane. This is particularly advantageous in the installations at high latitudes, in which, particularly in winter, the Sun reaches limited heights on the horizon during the day. On the other hand, it is advantageously possible to reduce the tilt angle of the reference plane in those cases where, for example for aesthetic reasons, it is desired to limit the vertical extension of the device as much as possible. This is particularly advantageous in urban and suburban areas, or in the case of installations exposed to particularly strong winds. From this standpoint, the device of the present invention is particularly adapted to be installed on buildings roofs.

In addition, since the tilt angle of the aforementioned reference plane also determines the necessary spacing between the different modules of the device, it is advantageously possible to increase the tilt angle of the aforementioned reference plane in those cases where it is desired to increase the density of modules on the reference plane, given the same incidence angle of the solar rays, above which there is no mutual shading.

Preferably, the support structure of the device of the present invention comprises a first framework slidably associated with the track and a second framework integrally associated with the first framework and comprising said reference plane.

Advantageously, the photoreceiver modules are therefore associated with a suitable frame (second framework) integral in rotation with a different frame (first framework) that is movable with respect to the fixed base frame. The azimuth movement is therefore achieved in a structurally simple and economical manner.

In a preferred embodiment of the device of the present invention, said at least one adjustment member comprises an arm of variable length that is operatively associated, at a first free end thereof, with the first framework, and is operatively associated at the opposite second free end thereof, with the second framework. Advantageously, the adjustment of the tilt angle of the aforementioned reference plane with respect to the support plane is therefore achieved in a structurally simple and economical manner.

Preferably, the second framework is defined by a plurality of reticular structures, preferably quadrangular, that are mutually associable. Such feature advantageously allows important savings in transport, weight and movement to be achieved.

In a preferred embodiment of the device of the present invention, the support structure comprises a plurality of blocks for the mounting of a plurality of photoreceiver modules, said blocks being associable with said support structure at a plurality of different positions. Advantageously, it is thus possible to vary the density of the modules on the device of the present invention as a function of the different selection criteria, such as for example the shading factor, the quantity of energy desired after the energy conversion, the conformation of the installation surface, etc. Such expedient moreover permits easy mounting on the device of modules with even very different geometric dimensions. In this manner, the application and use flexibility of the device of the present invention is further increased.

Moreover, in the cases where the installation site has a surface of irregular form, such as in the case of installation on building roofs, it is possible to attain an improved fill factor of the available surface by installing more devices of reduced size.

Preferably, the support structure of the photoreceiver modules is slidably associated with the track by the interposition of three wheels that are angularly spaced from each other. Advantageously, the provision of three wheels ensures stability and a lack of redundancy.

More preferably, the track has, in cross section, an edge profile and each wheel comprises a V-shaped groove coupled with said edge. The track is thus advantageously defined by a common section bar having a cross section provided with a sharp edge for the wheel coupling. Such cross section can be rectangular, square or more preferably L- or C-shaped, so to define an undercut portion adapted to cooperate with an L- or C-shaped element associated with the overlying structure in order to make an anti-overturning system.

In preferred embodiments of the device of the present invention, each wheel is rotatably mounted on a respective bracket associated with the support structure and extended along a direction tilted by an angle of predetermined amplitude with respect to a substantially vertical plane. In such a manner, the double function is carried out of support of the support structure of the photoreceiver modules and centring of the same on the track during the azimuth movement of the device, without having to employ specific centring elements which would inevitably increase the weigh and complicate the device structure, in addition to hindering maintenance operations.

Preferably, the aforementioned angle has an amplitude equal to 45°.

Preferably, the position of at least one wheel with respect to the track can be adjusted. More preferably, the aforementioned position can be adjusted by means of adjustment of the position of the respective bracket on the support structure. It is thus possible, by means of this technical feature, to perfectly adapt the three wheels to the track profile, thus being able to always obtain the desired stability and centring characteristics.

In a particularly preferred embodiment thereof, the device of the present invention further comprises a second motor group for controlling the movement of said at least one movement member, the first motor group and the second motor group being mounted on a single mechanical support associated with the aforementioned support structure. Advantageously, the provision of the two motor groups on a single mechanical support makes easier the device installation and maintenance operations, in addition to simplifying the transport of the aforesaid motor groups. It is also advantageously possible to protect both motor groups with a single case. Furthermore, maximum simplicity and savings is attained in the arrangement of the necessary wiring, since it is possible to provide a single canalization for both motor groups at a single zone of the device, such zone being able to be suitably chosen in such a manner that the motor groups do not hinder the maintenance operations.

Preferably, the first and second motor groups are of the same type and have the same size. Such feature permits attaining an advantageous inertia and mass equilibrium between the two motor groups, with consequent advantages in terms of stability.

Preferably, the aforementioned mechanical support is removably associated with the support structure, so to facilitate the possible substitution/removal of the same.

Preferably, the first motor is kinematically coupled to the aforementioned support structure by means of a first belt transmission comprising a toothed belt integrally associated with the track.

Preferably, the second motor group is kinematically coupled to said at least one photoreceiver module by means of a second toothed belt transmission comprising a gravity belt tightener.

Advantageously, the use of toothed belts both for the azimuth movement and for the altitude movement ensures the movement precision required by the application and avoids sliding, even with a low tightening of the belts themselves. The use of smooth belts, on the other hand, would have required much greater tightening levels, attainable by more complex, massive and costly devices, and sliding would have always been possible, since this is an outdoor application in which rain, ice or condensate can easily be present.

In a particularly preferred embodiment thereof, the device of the present invention comprises a plurality of movement members of photoreceiver modules kinematically coupled with each other by means of a plurality of mechanical deviation members adapted to make a synchronous movement of all the movement members.

Preferably, the base frame of the device of the present invention comprises three equidistant support feet. Advantageously, the provision of three support feet ensures high stability, avoiding any redundancy problem.

More preferably, each support foot is height-adjustable. It is thus advantageously possible to stably install the device of the present invention even on not-perfectly-flat surfaces.

In some embodiments of the present invention, the device comprises a plurality of photoreceiver modules, said modules being photovoltaic panels, or more preferably photovoltaic concentration modules.

Preferably, the photovoltaic modules are arranged along a plurality of parallel rows.

Further characteristics and advantages of the present invention will be clearer from the following detailed description of a preferred embodiment thereof, made with reference to the attached drawings. In such drawings:

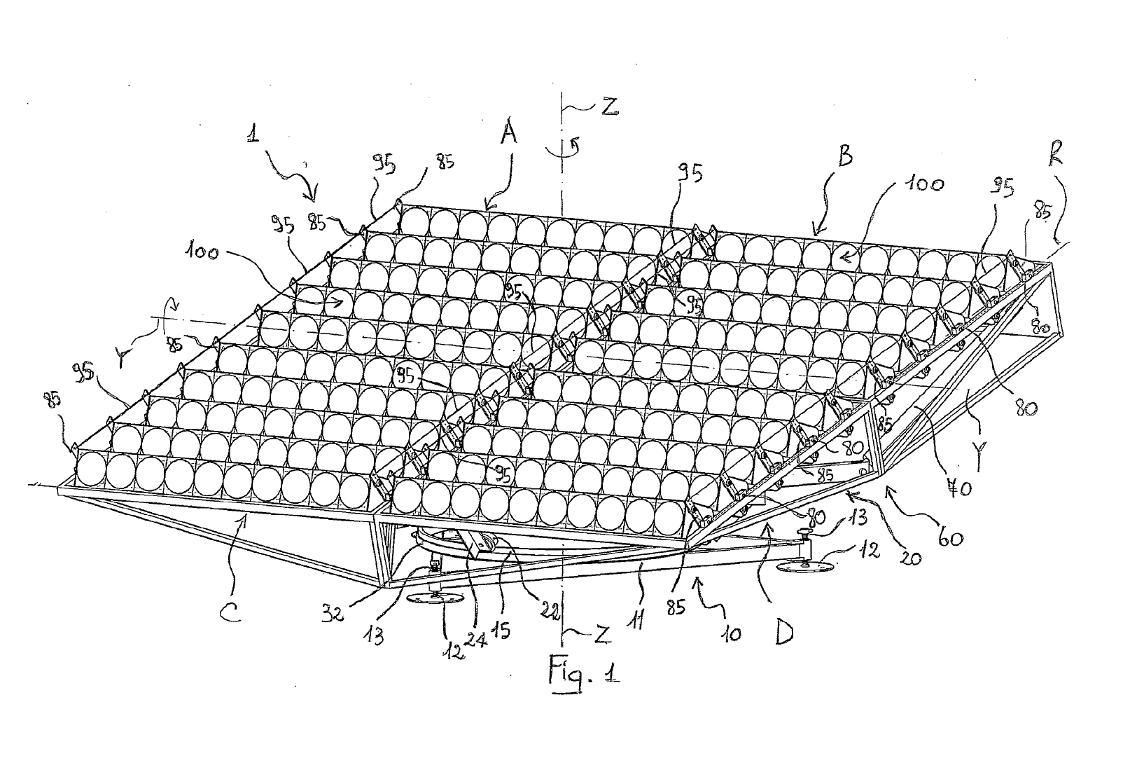

FIG. 1 is a front perspective schematic view of a preferred embodiment of the device of the present invention;

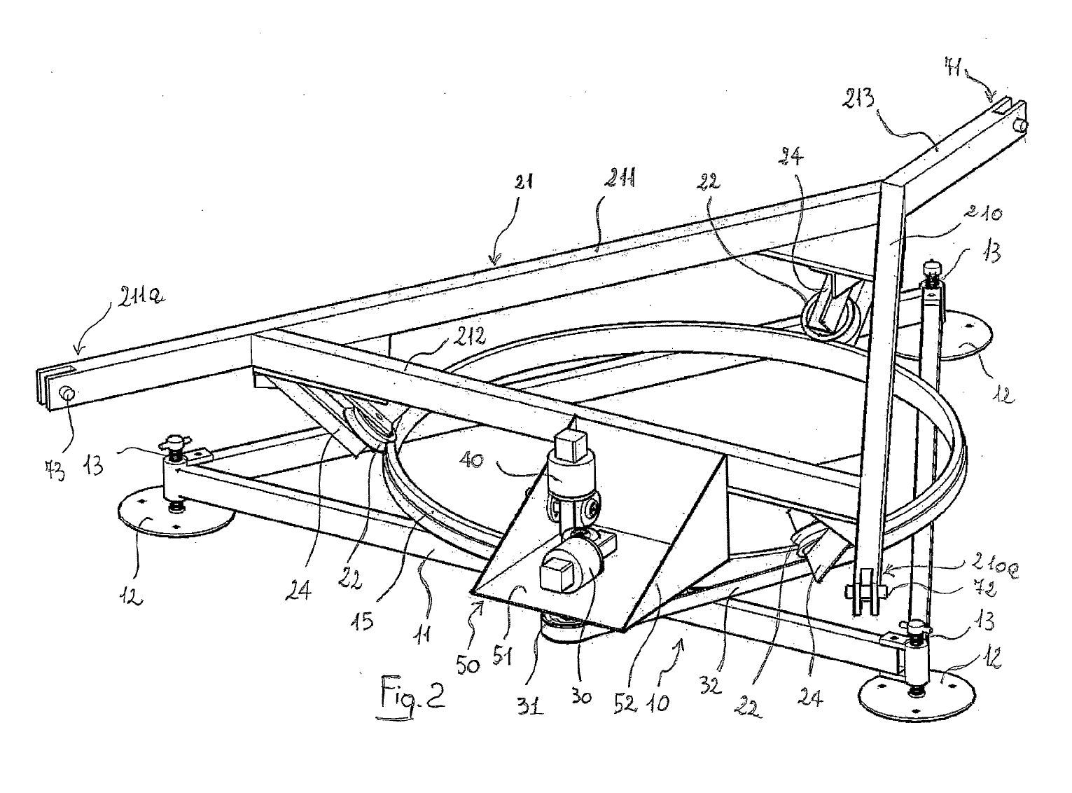

FIG. 2 is a perspective schematic view of a lower portion of the device of FIG. 1, from an observation point opposite that of FIG. 1;

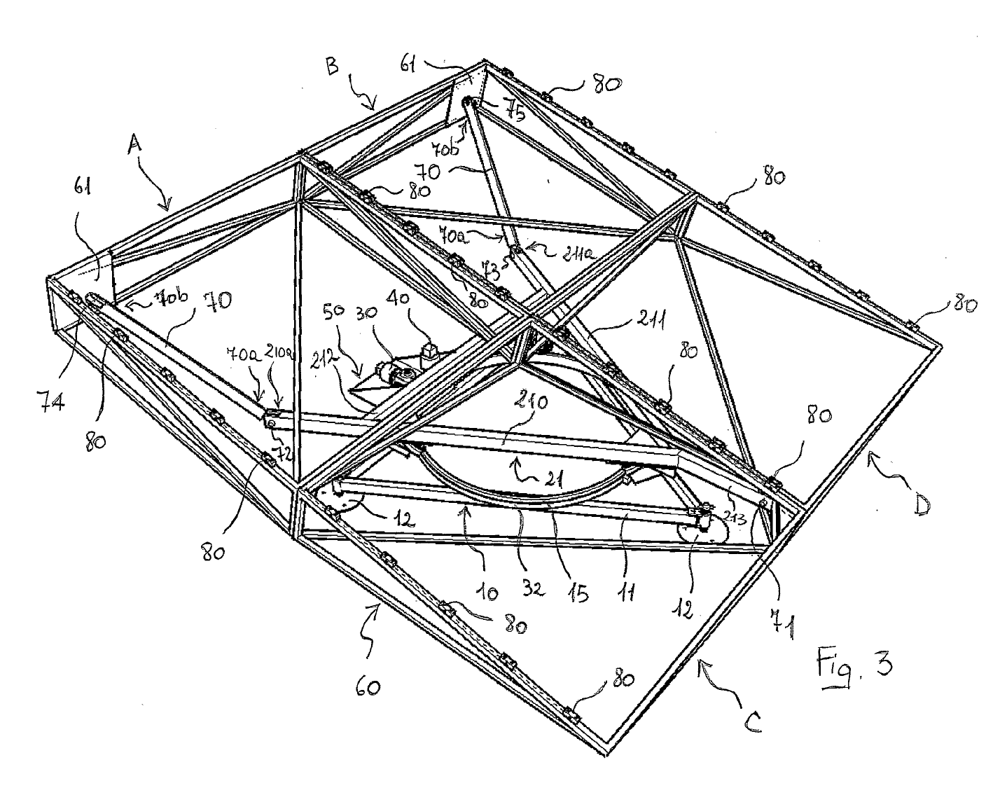

FIG. 3 is a top perspective schematic view of a portion of the device of FIG. 1 which comprises the portion of 2;

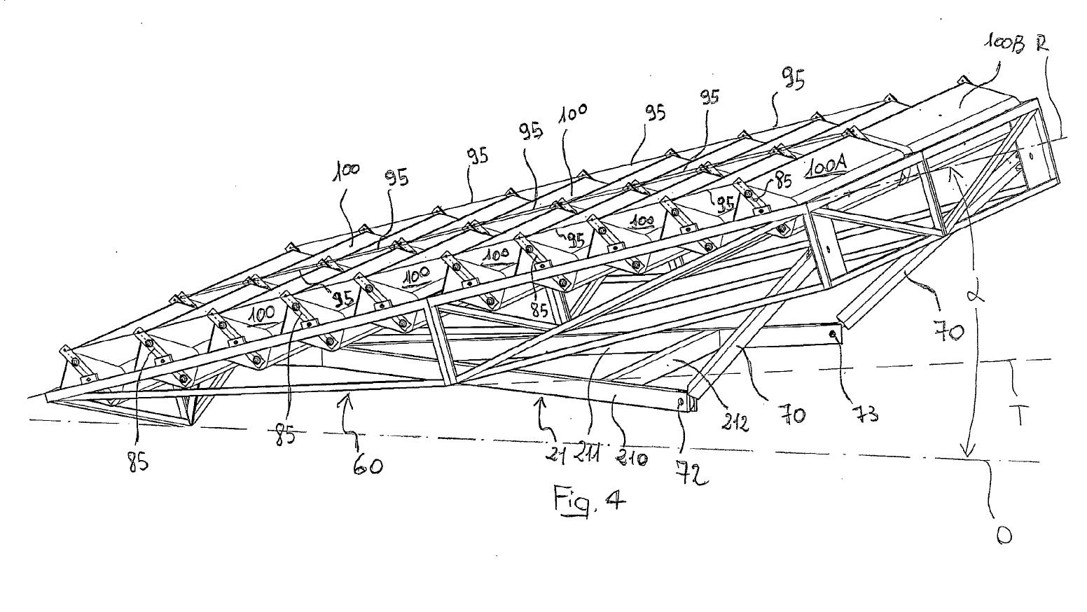

FIG. 4 is a side perspective schematic view of an upper portion of the device of FIG. 1;

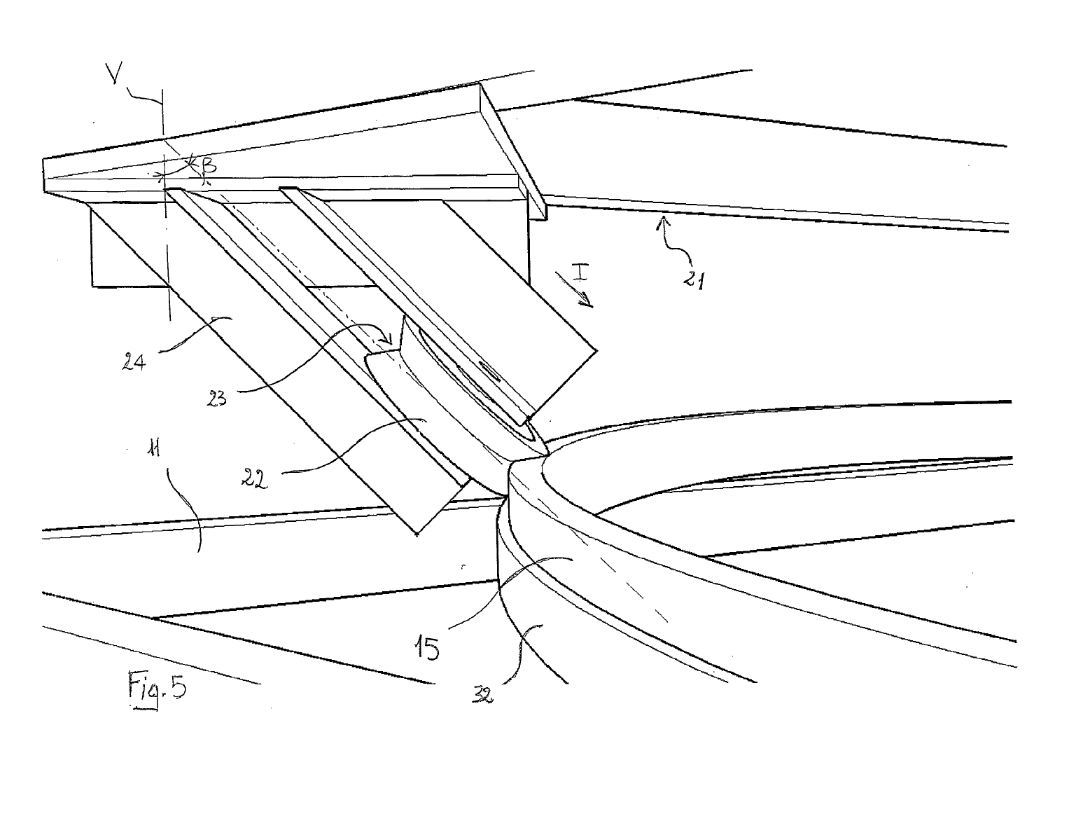

FIG. 5 is an enlarged perspective schematic view of a detail of the device of FIG. 1;

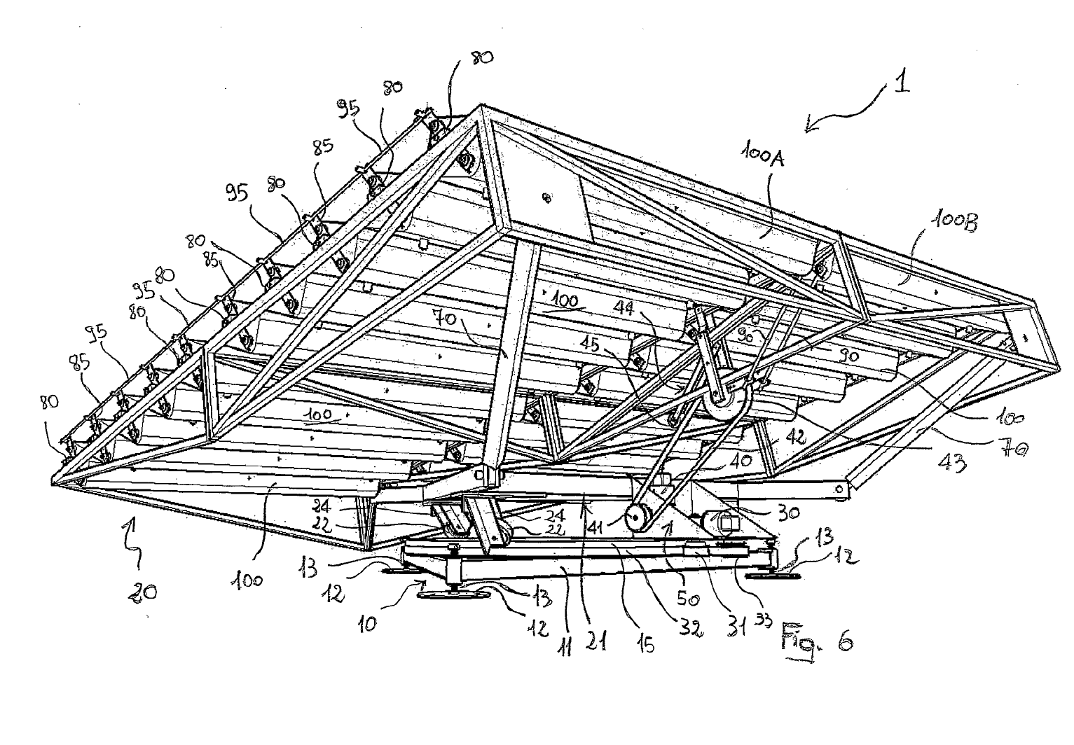

FIG. 6 is a perspective schematic view of the device of FIG. 1 from an observation point opposite that of FIG. 1.

In FIG. 1, a preferred embodiment of a sun tracker device in accordance with the present invention is indicated in its entirety, for merely exemplifying purposes, with the reference number 1.

The device 1 has a preferred application for the installation of photovoltaic cells (preferably of concentration-type) in a solar energy to electrical energy conversion plant. The device according to the present invention can however also be applied for the installation of solar panels in a solar energy to thermal energy conversion plant.

Device 1 comprises a plurality of photoreceiver modules 100 arranged in parallel rows. For greater illustration clarity, the reference number 100 is associated in the attached figures to only some of the aforementioned modules.

The modules 100 can be moved around a single vertical axis Z-Z in order to make the azimuth movement; each module row is then movable in rotation around a respective horizontal axis Y-Y (only one of which is indicated in FIG. 1) in order to make the altitude movement of the modules 100.

The photoreceiver modules can be of different type; in the embodiment illustrated in the figures, the modules 100 are photovoltaic concentration modules.

The device 1 can be part of a plant comprising a plurality of identical devices.

The device 1 is designed so that it can be easily mounted even by only two people, without the aid of particular equipment (like cranes), since it is made up of a limited number of pieces that are sufficiently manageable and light. In particular, no component of the device reaches 20 kg weight, and thus, according to current related laws, it can even by moved by a single person.

The device 1 is also conceived to be simply set on the ground or on a flat roof, without preliminary building works. In fact, the particular shape of the device of the present invention, its low centre of gravity, wide support base and very low sensitivity even to very strong winds permit such an installation type. In any case, for improved safety in case of exceptional weather events, the device 1 can be constrained to a robust anchoring point by means of a simple steel chain or cord. This installation mode permits considerable savings during installation, among other things avoiding, in the case of installation on flat building roofs, making holes or other works that are not always appreciated by the building owners.

The device 1 comprises a base frame 10 consisting of a triangular structure 11. The frame 10 is provided with three support feet 12. Each foot is height-adjustable by means of a screw 13. The base frame 10 defines a support plane O of the device 1; such plane O, in the ground installations, is typically horizontal, but it is possible to provide for installations on non-horizontal planes, such as for example in the installations on slanting roofs.

The adjustment of the planarity of the base frame 10 can be easily achieved onsite in a few seconds, by means of the aid of a simple level, by operating on two of the three screws 13.

On the base frame 10, a circular track 15 is fixed which supports the movable part of the device 1. In the embodiment illustrated in the attached figures, the circular track 15 is defined by a section bar having a rectangular cross section.

In a particularly preferred embodiment of the device 1, the track section bar 15 instead has an L- or C-shaped cross section, so to define an undercut portion adapted to cooperate with an L- or C-shaped element associated with the overlying structure in order to make an anti-overturning system.

A support structure 20 of the photoreceiver modules 100 is slidably mounted on the track 15.

The support structure 20 comprises, at a lower portion thereof, a triangular framework 21, defined by three arms 210, 211, and 212. Such framework 21, visible in detail in FIG. 2, is provided with three angularly equidistant wheels 22, each placed at a vertex of the triangular framework 21.

As is clearer in the detail of FIG. 5, the wheels 22 are provided with a V-shaped groove 23 slidingly coupled with one edge of the track 15.

The wheels 22 are also rotatably mounted by means of suitable bearings (not visible in the attached figures), on respective brackets 24 associated with the vertices of the triangular framework 21. The brackets 24 are extended along a direction (indicated with the arrow I in FIG. 5) that is tilted with respect to a vertical plane V by a predetermined angle β (this being indicated in FIG. 5 too) preferably having an amplitude equal to about 45°.

The position of at least one of the brackets 24 on the framework 21 can be adjusted, so to be able to perfectly adapt the wheels 24 to the track 15.

Advantageously, the provision of tilted wheels 24 permits avoiding the use of other mechanical elements for centring the support structure 20, such as for example a central pin, in this manner leaving the cylindrical space enclosed by the track 15 completely free. Such free space is particularly useful as an easy passage for the wires of the motor groups for the azimuth and altitude movements of the modules 100 and can also host the possible mechanical safety constraints mentioned above (steel wire or chain). In such space, possible boxes can also be placed for the conditioning electronics of the current produced by the photoreceiver modules, in the case they are photovoltaic panels.

As illustrated in FIG. 2, the azimuth and altitude movement of the modules 100 is attained by means of motor groups 30 and 40, both installed on a single mechanical support 50 that is removably associated with the framework 21. Such mechanical support 50 in particular comprises a bracket plate 51 which can be protected by a case (not illustrated).

The two motor groups 30, 40 are preferably of the same type and have the same size. Both the motor groups 30, 40 control the respective movements by means of respective belt transmission systems.

In particular, the motor group 30 controls the azimuth movement. It comprises a drive shaft projecting below the bracket plate 51 and on which a toothed pulley 31 is fit. A toothed belt 32 is engaged on such pulley 31, belt 32 operating between the pulley 31 and a smooth pulley 33 mounted on the lower face of the bracket plate 51 close to the toothed pulley 31.

The toothed belt 32 is arranged with the toothing turned on the side opposite the track 15, i.e. towards the outside of the device 1. The smooth face of the belt 32 therefore lies on the lateral surface of the track 15 and on the smooth pulley 33, while the toothed face of the belt 32 is engaged on the toothed pulley 31.

The belt 32 is integrally bound to the track 15, by means of a suitable locking constraint. In operation, the toothed pulley 31, engaging with the toothed belt 32 bound to the track 15, is moved around the track 15 by being wound on the belt 32, moving the framework 21 and thus the support structure 20 of the modules 100 in rotation around the vertical axis Z-Z. The anchoring zone of the belt 32 to the track 15 is oriented towards the south, so that the pulley 31 never interferes with the locking constraint.

In substance, the reversed belt solution described above works in an equivalent manner to a solution wherein the toothed pulley 31 is engaged on a big toothed wheel formed on the track 15, for example by means of milling or pressure die-casting. Such solution, however, would be more complex from the structural standpoint and therefore more expensive.

The motor group 40, on the other hand, controls the height movement of the modules 100. As illustrated in FIG. 6, the motor group 40 comprises a drive shaft projecting from a side surface 52 of the support 50, on which a toothed pulley 41 is fit. The drive shaft of the motor group 40 is therefore extended along a direction orthogonal to that in which the drive shaft of the motor group 30 is extended.

A toothed belt 42 engages on the toothed pulley 41, such belt 42 operating between the pulley 41 and a toothed pulley 43 mounted integral with the support structure 20 of the modules 100, as described better below. The tightening of the toothed belt 42 is attained by means of a gravity belt tightener 44, comprising a free pulley 45 provided with a suitable ballast that, due to the force of gravity, pushes the free pulley 45 against the belt 42, tightening it in an appropriate manner.

Preferably, the toothed pulley 43 has a diameter greater than that of the toothed pulley 41, so to introduce a motion reduction factor.

As illustrated in FIGS. 1, 3, 4 and 6, the support structure 20 comprises, at an upper portion thereof, a framework 60 on which the photoreceiver modules 100 are mounted.

The framework 60 is made by means of a tubular trellis, so to define a rigid and light structure. In particular, the framework 60 is defined by a modular structure formed by joining together a plurality of single reticular structures.

In the specific example illustrated in the attached figures, the framework 60 is made by means of four different reticular structures, indicated in FIGS. 1 and 3 with A, B, C and D. Preferably, each of these reticular structures has a square shape in a plan view, so that the frame 60 also has a square shape in a plan view.

As illustrated in FIG. 4, the framework 60 is defined between a base plane T, in the illustrated example substantially parallel to the support plane O (in general, it could however have a tilt with respect to said support plane O) and a top plane R that is tilted with respect to the base plane T. The top plane R defines the coupling plane of the photoreceiver modules 100 to the framework 60. In the illustrated example, the top plane R is tilted by an angle of about 15° with respect to the base plane T. Such angle can however a different value.

The aforementioned tilt is obtained by making two of the four reticular structures A, B, C and D (structures C and D in FIGS. 1 and 3) with a triangular lateral profile and the other two (structures A and B in FIGS. 1 and 2) with a rectangular lateral profile.

The framework 60 is coupled to the framework 21 so to be integral with the framework 21 in the azimuth movement.

In particular, as illustrated in FIG. 3, the frame 60 is coupled to the framework 21 at a hinge 71 provided on a free end portion of an arm 213 extended from the junction vertex of the arms 210 and 211. In particular, the hinge 71 is provided on the contacting sides of the reticular structures C and D.

On the opposite side of the pin 71 with respect to the base frame 10, the frame 60 is coupled to the framework 21 by means of a pair of arms 70 of adjustable length.

In particular, the arms 70 are coupled, at first free ends 70a thereof, to respective hinges 72, 73 provided at free ends 210a and 211a of the arms 210, 211. At the opposite free ends 70b thereof, the arms 70 are coupled to respective hinges 74, 75 provided on suitable plates 61 associated with the framework 60. The hinges 74 and 75 are provided on the end sides of the reticular structures A and B.

In practice, the arms 70 of adjustable length, interfacing directly with the hinges 72, 73 located on two vertices of the triangular framework 21 and indirectly (by means of the framework 60) with the hinge 74 located on the other vertex of the triangular framework 21, determine the amplitude of the angle α between the top plane R and the support plane O of the device (FIG. 4). By varying the length of the arms 70, the rotation of the framework 60 around the axis of the hinge 71 is attained, in this manner varying the amplitude of the angle α.

Preferably, the angle α has a minimum amplitude in the range between about 10° and about 30°, and still more preferably in the range between about 15° and about 25°.

The framework 60 is moreover provided, on the upper face thereof, with a plurality of blocks 80 for the mounting of the photoreceiver modules 100. For illustration clarity, in the attached figures, the reference number 80 is associated only with several of the aforementioned blocks.

The blocks 80 are associated with respective holes of a plurality of holes formed on the upper face of the framework 60.

The holes on the upper face of the framework 60 are such that the position of the blocks 80 on the framework 60 can be varied, so to vary the mutual spacing of the modules 100.

The blocks 80 are preferably made of a synthetic material and are appropriately drilled for housing a hinging axis of the modules 100.

The height movement of the modules 100 occurs in the following manner.

The modules 100 of the various parallel rows are synchronously moved by means of respective movement members 85 associated with the blocks 80, so to be rotatable around respective horizontal axes Y-Y that are parallel to each other. For more illustration clarity, in the attached figures, the reference number 85 is associated only with several of the movement members.

The aforementioned movement, as already said, is controlled by the motor group 40, which controls the rotation of the toothed pulley 43 by means of the toothed belt 42.

As illustrated in FIG. 6, a pair of deviation rods 90 are coupled in an eccentric manner to the pulley 43, such rods 90 being connected to a pair of modules 100 (in FIG. 6 the modules of such pair of modules are indicated with 100A and 100B) by means of the respective movement members 85. Such modules in turn transmit the movement to the other module rows by means of further deviation rods 95. For greater illustration clarity, the reference number 95 is associated only with some of the aforesaid deviation rods.

Substantially, both the motion transmission system from the pulley 43 to the pair of modules 100A, 100B and that from the pair of modules 100A, 100B to the other rows of modules is of the crank-connecting rod type.

The deviation rods are provided with an adjustment system (not visible), defined by a screw and a pair of nuts and counter nuts, for adjusting the tilt of each photovoltaic module 100 with respect to the adjacent one so to ensure the perfect alignment of all modules 100.

From that described above, it is clear how the device 1 of the present invention allows modifying the orientation of the photoreceiver modules 100 while the position of the sun during its passage from sunrise to sunset changes, always maintaining a desired orientation, which is that in which the detection surface of such modules is in a position substantially perpendicular to the incident solar light. The use of such device is therefore particularly advantageous in the case in which the photoreceiver modules 100 are photovoltaic concentration modules. For the correct functioning of the concentration modules, it is in fact necessary that the direction of the incident solar rays on the modules is perfectly orthogonal to the detection surface of the modules themselves, with a tolerance of some tenths of a degree, and the device according to the present invention is capable of satisfying this particular need.

Finally, the device of the present invention allows achieving an optimal compromise between maximisation of the energy yield of the device and minimisation of the size of the device, at the same time ensuring an easy access to the components of the device for the maintenance operations.

Naturally, a man skilled in the art can make further modifications and variations to the above-described finding, with the goal of satisfying specific and contingent needs, such variants and modifications in any case being within the scope of protection as defined by the attached claims.

1-24. (canceled)

25. A sun tracker device, comprising:
a base frame provided with a track that is at least in part circular, said base frame defining a support plane;
a support structure of at least one photoreceiver module, the support structure being slidably associated with the track and comprising a reference plane for coupling to said at least one photoreceiver module;
a first motor group for controlling movement of the support structure on the track around a substantially vertical axis; and
at least one movement member of said at least one photoreceiver module around a respective substantially orthogonal axis,
wherein said reference plane is tilted, with respect to said support plane, by an angle of predetermined amplitude.

26. The device according to claim 25, wherein said angle has an amplitude between about 5° and about 50°.

27. The device according to claim 25, comprising at least one adjustment member of the tilt of said reference plane with respect to the support plane.

28. The device according to claim 25, wherein the support structure comprises a first framework slidably associated with the track and a second framework integrally associated with the first framework and comprising said reference plane.

29. The device according to claim 28, comprising at least one adjustment member of the tilt of said reference plan with respect to the support plane, wherein said at least one adjustment member comprises an arm of variable length, operatively associated, at a first free end thereof, with the first framework and, at an opposite second free end thereof, with the second framework.

30. The device according to claim 28, wherein said second framework is defined by a plurality of mutually associable reticular structures.

31. The device according to claim 25, wherein the support structure comprises a plurality of blocks for the mounting of a plurality of photoreceiver modules, said blocks capable of being associable with said support structure at a plurality of different positions.

32. The device according to claim 25, wherein the support structure is slidably associated with the track by the interposition of three wheels which are angularly equidistant from each other.

33. The device according to claim 32, wherein the track has an edge profile in cross section, and each wheel comprises a V-shaped groove coupled with said edge.

34. The device according to claim 32, wherein each wheel is rotatably mounted on a respective bracket associated with the support structure and extended along a direction tilted by an angle of predetermined amplitude with respect to a substantially vertical plane.

35. The device according to claim 34, wherein said angle has an amplitude equal to about 45°.

36. The device according to claim 34, wherein the position of at least one wheel with respect to the track is adjustable.

37. The device according to claim 36, wherein said position is adjustable by adjusting the position of the respective bracket on the support structure.

38. The device according to claim 25, further comprising a second motor group for controlling movement of said at least one movement member, wherein the first motor group and the second motor group are mounted on a single mechanical support associated with said support structure.

39. The device according to claim 38, wherein the second motor group is of a same type and has a same size as the first motor group.

40. The device according to claim 38, wherein said mechanical support is removably associated with the support structure.

41. The device according to claim 25, wherein said first motor is kinematically coupled to said support structure by means of a first belt transmission comprising a toothed belt integrally associated with the track.

42. The device according to claim 38, wherein the second motor group is kinematically coupled to said at least one photoreceiver module by means of a toothed belt transmission comprising a gravity belt tightener.

43. The device according to claim 42, comprising a plurality of movement members of the photoreceiver modules kinematically coupled to each other by means of a plurality of mechanical deviation members capable of being adapted to make a synchronous movement of all the movement members.

44. The device according to claim 25, wherein the base frame comprises three support feet that are equidistant from each other.

45. The device according to claim 44, wherein each support foot is height-adjustable.

46. The device according to claim 25, comprising a plurality of photovoltaic panels.

47. The device according to claim 25, comprising a plurality of photovoltaic concentration modules.

48. The device according to claim 25, comprising a plurality of photoreceiver modules arranged along a plurality of parallel rows.
